(19) United States
(12) Patent Application Publication
(10) Pub. No.: US 2001/0046123 A1
(43) Pub. Date: Nov. 29, 2001

(54) Space utilization inside of a computer case

(76) Inventor: Daniel K. Wedding, Toledo, OH (US)

Correspondence Address: Dr. Daniel K. Wedding, 4525 Wedgewood Ct., Toledo, OH, 43615, US

(21) Appl. No.: 09/755,149

(22) Filed: Jan. 8, 2001

Related U.S. Application Data
(60) Provisional application No. 60/174,918, filed on Jan. 10, 2000.

(51) Int. Cl. G06F 1/16; H05K 5/00

(52) U.S. Cl. 361/727; 361/726; 361/724; 361/683

(57) ABSTRACT

This invention relates to a functional use for uncommitted computer bays. Uses include a storage holder for various types of computer software including but not limited to compact disks, jewel cases, floppy disks, floppy disk cases, tapes, tape cases, zip disks, zip disk cases, and/or any object that can be placed within its confines including but not limited to wallets, keys, coins, nuts, bolts, and so forth.

### RELATED APPLICATION

Claim of priority of provisional application 60/174,981 filed on Jan. 10, 2000

### BACKGROUND

The inside of a computer case or enclosure is mostly empty space. This invention comprises utilization of this space. Most existing computer cases or enclosures have openings that are used to hold peripherals such as disk drives, hard drives, floppy drives, zip drives, and so on. These openings are called bays. When a bay is not occupied, a cover plate is typically mounted over the bay to conceal the unused space. Most computer cases have one or more unused bays, depending on the type of case. This space is currently wasted. In accordance with the practice of this invention, this space is utilized with a functional insert. In one embodiment, older cases are retrofitted with one or more inserts to occupy the unused bays. In a second embodiment, newer cases are designed and manufactured so that inserts can be used to access the space inside the case.

### BRIEF SUMMARY OF THE INVENTION

This invention comprises a space utilization insert that will allow a user to access and utilize the space inside of a computer case or enclosure for storage and not for computer components. This space utilization invention provides functional insert assemblies such as shelves, drawers, compartments, and/or like storage assembly inserts to utilize the empty space inside of the computer case. Such inserts may be removable or may be integrated permanently into the case.

### BRIEF DESCRIPTION OF THE DRAWINGS

Reference is made to the drawings and FIGS. 1 to 9.

FIG. 1 shows a computer case with n bays.

FIG. 2 show a computer case with 1 open storage bay and n inserts.

FIG. 3 shows two embodiments of different sized inserts for use in one or two empty bays, the mounting methods are not shown in this figure.

FIG. 4 shows various embodiments of integrated mounting methods for the insert.

FIG. 5 shows an embodiment of an external mounting method for the insert.

FIG. 6 shows an embodiment of an insert with smooth inside walls for storage of any item that will fit inside of the insert. The mounting methods described in FIGS. 3 and 4 are not shown in this figure.

FIG. 7 shows an embodiment of an insert with non-smooth inside walls, these forms are used for a specialized purpose like holding compact disks, floppy disks, zip disks, coins and the like. The mounting methods described in FIGS. 3 and 4 are not shown in this figure.

FIG. 8 shows an embodiment of the insert with a door and a method to lock the door. The mounting methods described in FIGS. 3 and 4 are not shown in this figure.

FIG. 9 shows an embodiment of the insert with a drawer, this drawer may or may not be pulled all the way out. This embodiment may be used to hold coins, nuts, bolts, specialized adapters, and the like. The mounting methods described in FIGS. 3 and 4 are not shown in this figure.

### DETAILED DESCRIPTION OF THE INVENTION

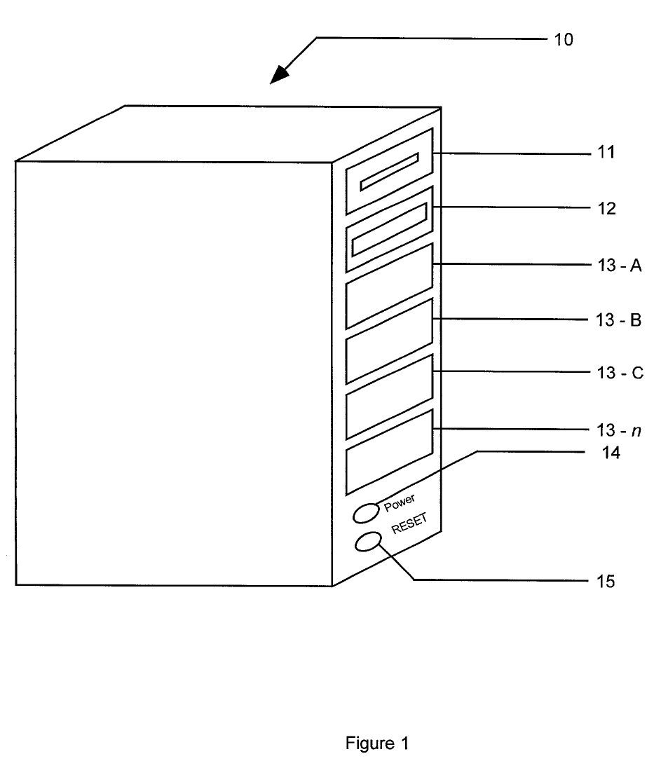

FIG. 1 shows a three-dimensional view of a standard computer case 10 with a floppy drive 11, compact disk drive 12, cover plates 13-A, 13-B, 13-C, 13-n, that conceal the unused drive bays, the computer's power button 14 and reset button 15. Due to the large variety of computer cases on the market, a generic case is shown in this figure and is used throughout.

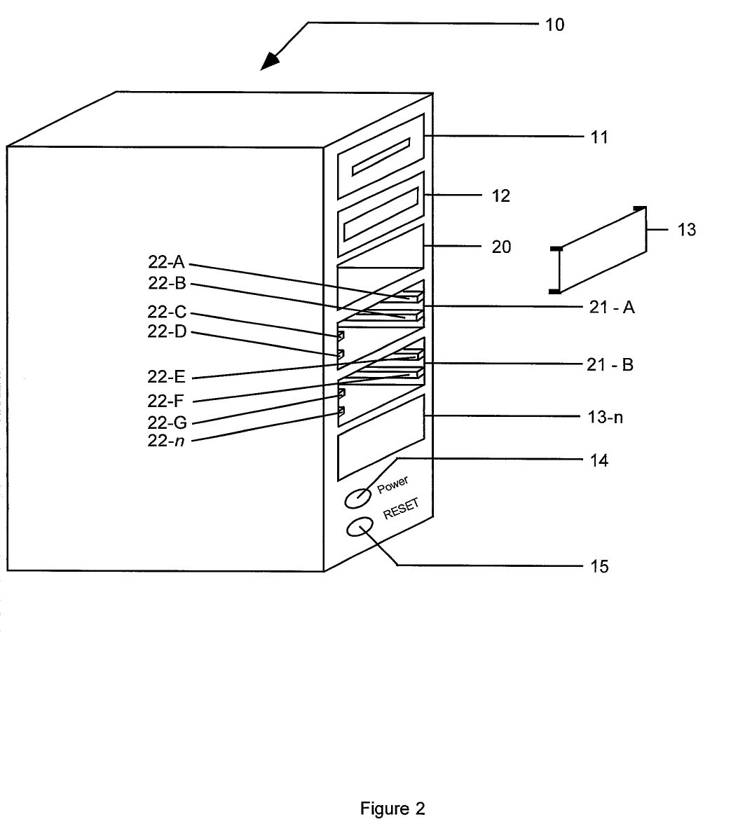

In one embodiment, previously manufactured and/or new computer cases are retrofitted to utilize a functional insert to allow access to and utilization of the unused bay space. This is accomplished by removing the cover plate from any of the unused bays and providing means for a functional insert to be put inside of the unused bay as shown in FIG. 2. This concept allows a computer user to access the unused space inside of the computer case. This is shown in FIG. 2 where the two lower cover plates are removed and two functional inserts are installed into the exposed bays.

In another embodiment, new cases are designed and manufactured to utilize the space with or without using a vacant bay though the use of a functional insert. In this embodiment, the functional insert will serve the same purpose as embodiment one. It allows access to and utilization of the space inside of the computer. In newly designed and manufactured cases the functional insert may or may not occupy an unused bay. Newly designed cases can have the inserts located in part of the case that will not occupy and unused bay. This does not preclude the use of vacant bays for the same function as in embodiment one. In newly designed cases, the functional insert may be integrated into the case without the size limitations of a drive bay.

FIG. 2 shows a three-dimensional view of the same computer case 10 in figure one, with floppy drive 11, compact disk drive 12, and open drive bay 20, after cover plate 13 has been removed, two open drive bays with inserts 21-A and 21-B installed. Inserts 21-A and 21-B are an insert embodiment that holds compact disk jewel cases with fins 22-A through 22-n. The inserts are not limited to this embodiment.

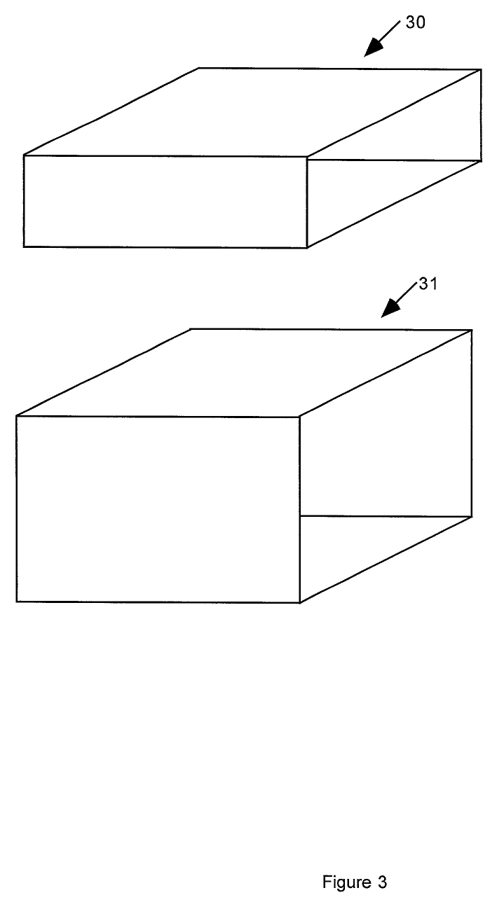

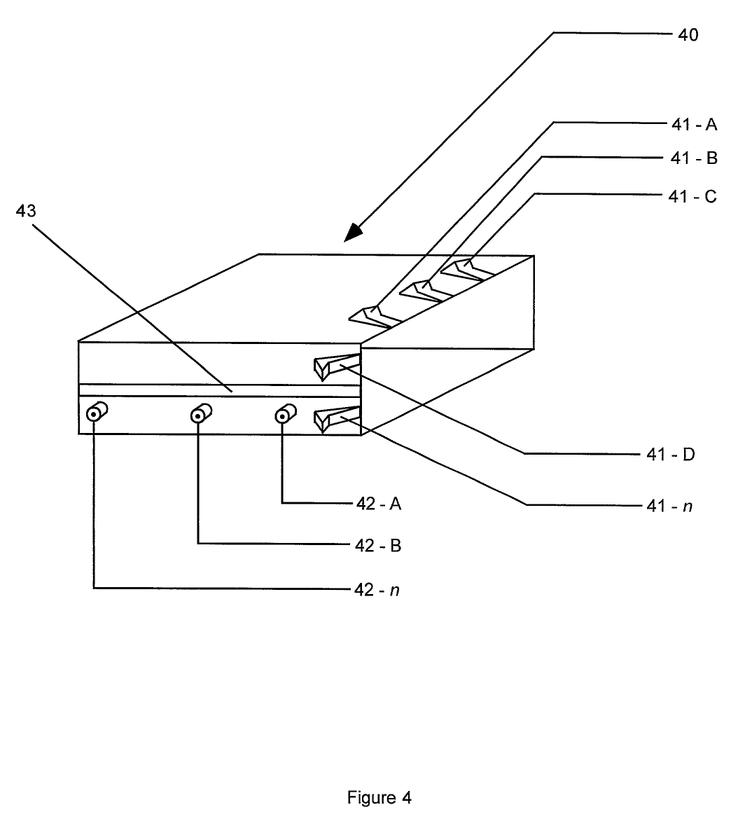

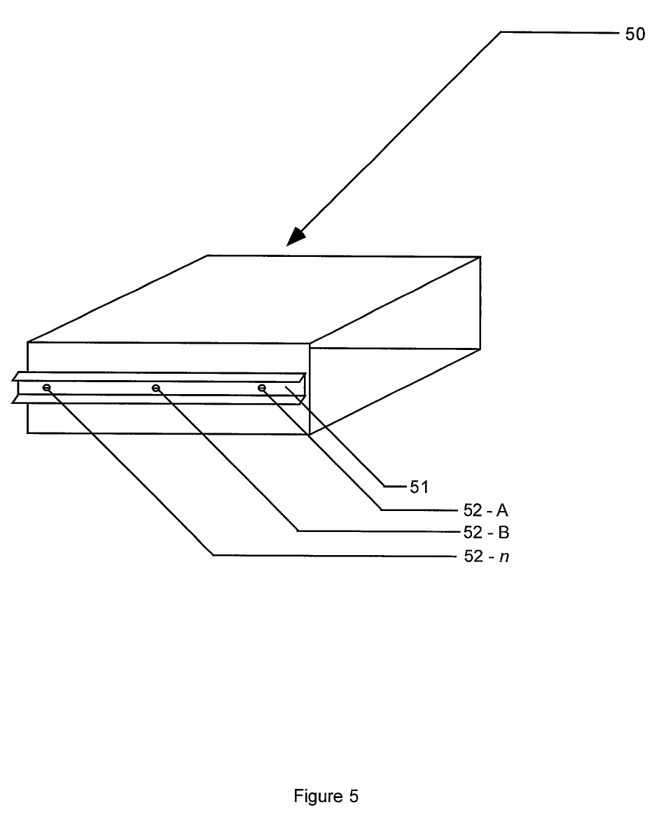

FIG. 3 is a three dimensional view of inserts 30 and 31, insert 31 being a double bay insert. Some computer cases have only one unused bay and allow for only one insert, while other cases have more unused bays and allow for a multiplicity of single bay inserts. For computers with multiple unused bays, a single insert is contemplated that occupies two or more bays. The inserts in this figure have smooth inside walls so they have a generic purpose, but multi-bay inserts are not limited to a smooth wall embodiment. For simplicity, the mounting methods described in FIGS. 4 and 5 are not shown in this Figure.

FIG. 4 shows a three dimensional view of one insert 40 for the practice of this invention. Due to the large variety of computer cases in existence, there is a need for multiple ways to install the insert into a case. The insert 40 contains a variety of mounting mechanisms that include locking tabs 41-A, 41-B, 41-C, 41-D, 41-n, holes for mounting screws or rivets 42-A, 42-B, 42-n, and a mounting groove 43. These mounting mechanisms as well as many others known in the art (but not shown in this figure) may be used singularly or in combination to mount the insert 40 inside any of the unused bays (element 20 in FIG. 2) of the computer case (element 10 of FIGS. 1 and 2) once the cover plate (element 13 of FIGS. 1 and 2) is removed. The mounting mechanisms may be an integral part of the insert 40.

In one embodiment of the practice of the invention, the mounting means for the insert would be a set of hooks that are on the sides of the functional insert close to the front of the case. This mounting method is similar to the method that is used to attach cover plates on the front of computer cases in order to hide the unused bay. In another embodiment of the practice of this invention, screws can be used to secure the insert into the bay in a similar manner to the way some peripherals are mounted, as shown in FIG. 4. In this embodiment, the insert would have a means of receiving a screw in locations that align with the screw hole locations in the bay. A screw is then inserted through the hole of the bay and into a receptacle on the side of the insert. Due to the large variation in cases on the market, a variety of mounting methods may be considered to assure the maximum compatibility between insert and case.

FIG. 5 is a three-dimensional view showing an insert 50 with external mounting rails 51. The rails could be the same rails that would be used on the case to mount peripherals, such as disk drives. A duplicate mounting rail (not shown) may be on the opposite hidden side of the insert 50. Each mounting rail 51 is attached to the insert 50 with n number of screws or rivets 52-A through 52-n. The rails 51 may also be attached by other mechanisms including, but not limited to, adhesives and welding. These mounting mechanisms as well as many others known in the art (but not shown in this figure) may be used singularly or in combination to mount the insert 50 inside any of the unused bays (element 20 in FIG. 2) of the computer case (element 10 of FIGS. 1 and 2) once the cover plate (element 13 of FIGS. 1 and 2) is removed. The mounting method may be a separate piece from insert 50.

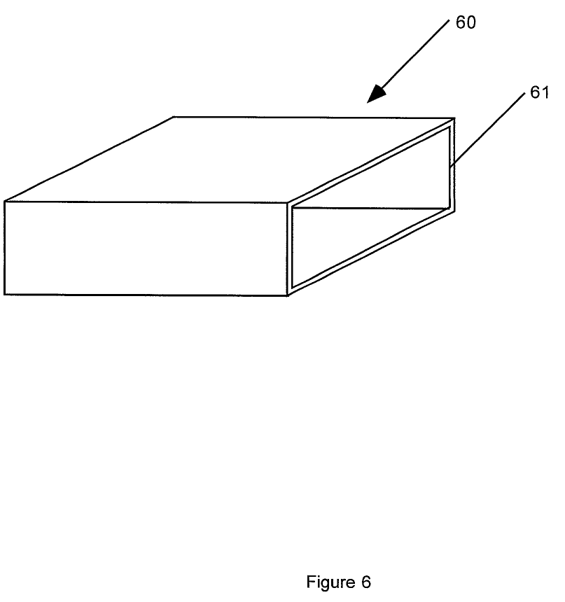

FIG. 6 shows an embodiment of the insert 60 with smooth inside walls 61. This insert can be used to store any object or objects that is desired such as coins, keys, wallets, and so forth. For simplicity, the mounting methods described in FIGS. 4 and 5 are not shown in this Figure.

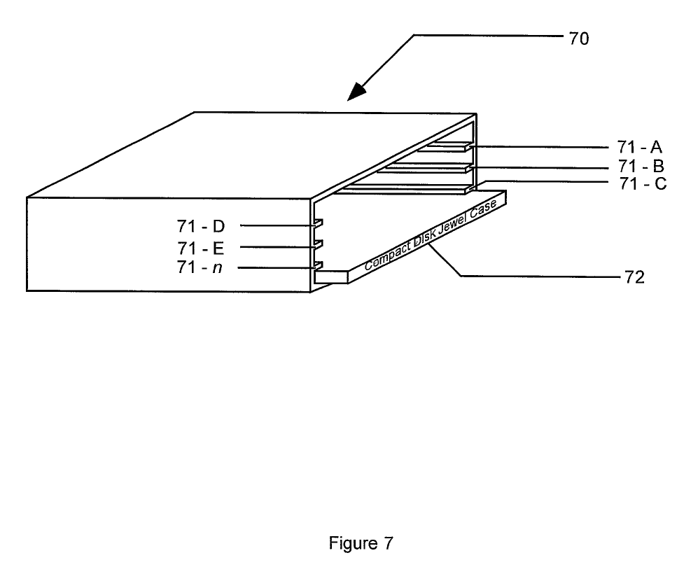

FIG. 7 shows an embodiment of the insert 70 with non-smooth inside walls. The inside walls of this insert have fins 71-A through 71-n for the purpose of holding a compact disk jewel case. These fins could be molded into the inside of the insert, or the insert could be made with thicker walls and grooves could be cut into the inside walls of the insert. The size, shape, and location of the fins (or grooves) may be altered in order to hold floppy disks, zip disk, tape reels, or any other like object. The inside of the insert can be with a specified shape to hold specific objects through the use of a custom molded interior of the insert. This insert can be used to store any object or objects that is desired and is not limited to the object(s) that the insert was customized to hold. For example, an insert with fins or grooves could also be used to store a set of keys when it is not filled with CDs. For simplicity, the mounting methods described in FIGS. 4 and 5 are not shown in this Figure.

One embodiment of the functional insert is an insert that would hold one or more compact disk jewel cases. Musical CDs and software CDs are stored in a jewel cases that are a standard size. Some programs require a CD in the CD drive in order for the program to run. When the program is not in use, the CD is removed from the CD drive and stored in the jewel case. In accordance with this invention, a functional insert is provided in an unused bay for a convenient and inexpensive storage location for the jewel case. This functional insert also provides storage location for but not limited to musical CDs, entertainment CDs, DVDs, jewel cases, and/or educational CDs. An example of this embodiment is shown in FIG. 7.

This space utilization invention is not limited to CDs. There are variations on the functional insert for different storage needs. For example, the functional insert may be a bin, shelf, drawer, or the like to hold computer storage media including but not limited to floppy disks, zip disks, super-floppies, tape backups, or any other current or future computer storage media. A functional insert bin, shelf, drawer, or the like may also be used to store items other than computer media such as money, keys, paper clips, or anything that the user put in the bin. Functional inserts can be designed to hold small note pads, tape, paper clip, pens, pencils, and other office supplies. Functional inserts are of different sizes so that if more than one bay is unoccupied; a single insert could be put into multiple bays to provide a more effective and efficient use of the space as shown in FIG. 3.

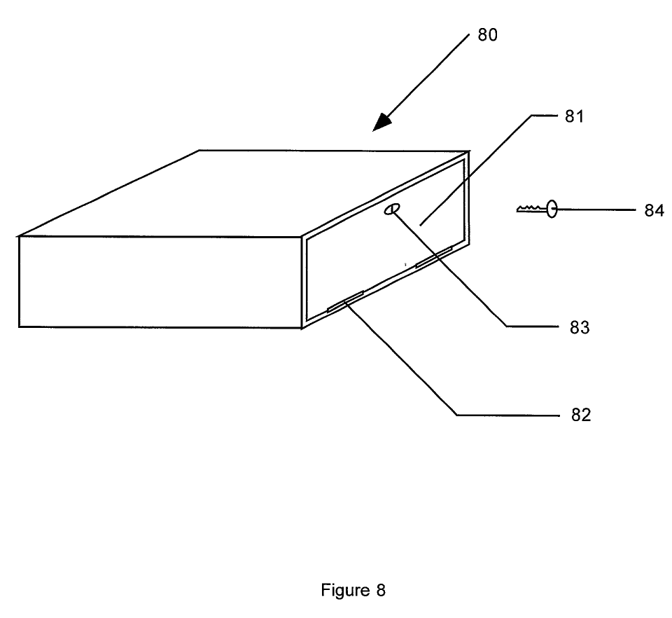

FIG. 8 shows a three dimensional view of another embodiment of insert 80 with a door (or cover) 81 to restrict access to the contents of the insert. The door (or cover) 81 may or may not have a hinge or hinges 82, attaching the door (or cover) 81, to the insert 80. The door (or cover) may be held closed by a lock 84. The lock, for the purpose of holding the door (or cover closed) can take the form of magnets, springs, clips, levers, latches, friction, mechanical, chemical, electrical, electro-mechanical devices, or other methods known in the art of locks. If a traditional lock is used, as shown with 83, a key 84 may be used to unlock the locking mechanism 83. With other types of locks, other methods of opening or closing the door (or cover) may be used such as a lever, latch, magnetic wand, a signal from the computer, a combination (for use with combination locks), or any other method known in the art. For simplicity, the mounting methods described in FIGS. 4 and 5 are not shown in this Figure.

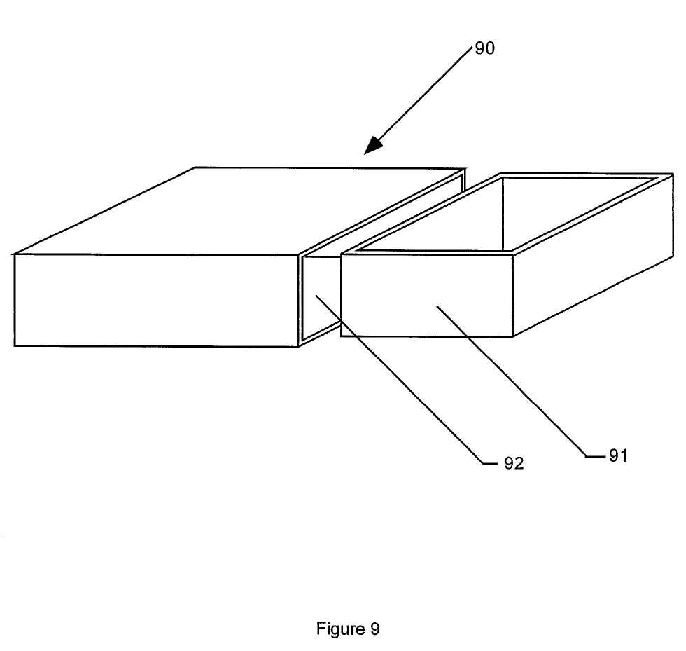

FIG. 9 shows a standard insert 90 with a pull out drawer 91 and a space provided by the insert for the drawer to be placed 92. The embodiment that is shown in FIG. 9 shows a drawer that is fully removable from the insert. Other embodiments may not be fully removable. The drawer may be pulled out by any method including, but not limited to, knobs, pulls, magnets, electromechanical devices, tracks, slides, glides, and/or any other method known to the art used singularly or in combination. For simplicity, the mounting methods described in FIGS. 4 and 5 are not shown in this Figure.

Functional inserts can be interchangeable so that a user may have one CD bay, one floppy bay and an open bay for coins. If the user decides to change the type of storage compartment, he/she could remove the current functional insert and replace it with a different style, type, or size. Functional inserts may have doors or covers (or not). Functional inserts with doors may have locks (or not). The locks may be mechanically, electrically, electro-mechanical, magnetic, chemical, and/or computer controlled. Colorful or decorative materials such as colored plastic could be used to manufacture the inserts in order to “Jazz” up the front of the computer or as a means of organization.

1. In a computer case having one or more vacant bays for receiving peripherals, the improvement comprises a storage assembly and means for mounting said assembly into one or more of said bays.

2. The invention of claim 1, wherein the storage assembly mounting hardware is an integral part of the storage assembly.

3. The invention of claim 1 wherein the storage assembly uses one or more of the unused bays.

4. The invention of claim 1 wherein the storage assembly has a door, access panel, cover, and/or plate.

5. The insert of claim 1 wherein the storage assembly has a locking mechanism in order to block or allow access to the contents of the insert.

6. The invention of claim 5 wherein the storage assembly's lock is mechanical, electrical, chemical, magnetic, frictional, computer controlled, and/or any combination thereof.

7. The invention of claim 1 wherein the storage assembly has the ability to slide out of the storage assembly in a manner similar to a drawer.

8. The invention of claim 1 wherein the storage assembly has the ability to be removed from the computer to act as a portable storage device.
